(19) United States
(12) Patent Application Publication
(10) Pub. No.: US 2011/0112782 A1
(43) Pub. Date: May 12, 2011

(54) BATTERY STATUS DETECTION DEVICE

(75) Inventors: Yoshihide Majima, Tokyo (JP); Kazuhiko Takeno, Kanagawa (JP); Haruo Uemura, Kumamoto (JP); Yasuyuki Kanai, Tokyo (JP); Takayuki Kanai, Kanagawa (JP)

(73) Assignees: MITSUMI ELECTRIC CO., LTD, TOKYO (JP); NTT DOCOMO, TOKYO (JP)

(21) Appl. No.: 13/003,357

(22) PCT Filed: Jul. 7, 2009
(86) PCT No.: PCT/JP2009/062356

§ 371 Date: Jan. 10, 2011

(30) Foreign Application Priority Data
Jul. 11, 2008 (JP) 2008-181924

(51) Int. Cl. G01R 31/36; G01N 27/416

(52) U.S. Cl. 702/63; 324/427

(57) ABSTRACT

A battery status detection device for detecting the status of a secondary battery 200 supplying power to a mobile device 300 includes a voltage detection unit 20 detecting voltages of the secondary battery 200; a current detection unit 30 detecting charge/discharge currents of the secondary battery 200; an arithmetic processing unit 50 calculating an internal resistance value of the secondary battery 200 based on a voltage difference between the voltages detected by the voltage detection unit 20 before and after the start of charging the secondary battery 200 and a current difference between the charge/discharge currents detected by the current detection unit 30 before and after the start of charging the secondary battery 200 and determining whether the secondary battery 200 is degraded based on the calculated internal resistance value; and a communication processing unit 70 outputting a signal indicating the determination result of the arithmetic processing unit 50.

### TECHNICAL FIELD

An aspect of the present invention relates to a battery status detection device for detecting the status of a secondary battery supplying power to an electric load.

### BACKGROUND ART

As a battery degrades, the battery operating time of an electric load such as an electronic device receiving power from the battery gradually decreases. A major reason of the degradation is assumed to be the increase in the internal resistance of the battery. Based on this assumption, methods for determining the degradation of a battery based on a calculated internal resistance have been proposed. Patent documents 1 through 4 disclose methods for calculating the internal resistance of a battery based on voltage-capacity characteristics of the battery, an open-circuit voltage of the battery, or a voltage and a current measured while the battery is discharging or being charged with a constant current.
[Patent document 1] Japanese Patent Application Publication No. 2001-228226
[Patent document 2] Japanese Patent Application Publication No. 8-43505
[Patent document 3] Japanese Patent Application Publication No. 2006-98135
[Patent document 4] Japanese Patent Application Publication No. 2002-75461

### DISCLOSURE OF INVENTION

### Problems to be Solved by the Invention

However, if the consumption current of an electric load such as an electronic device receiving power from a secondary battery changes frequently, it is difficult to accurately and stably detect the charge/discharge current and the voltage of the secondary battery by simply performing a detection process periodically.

An aspect of the present invention provides a battery status detection device that can determine whether a secondary battery is degraded even if the consumption current of an electric load receiving power from the secondary battery varies frequently.

### Means for Solving the Problems

In an aspect of this disclosure, there is provided a device detecting the status of a secondary battery supplying power to an electric load. The device includes a voltage detection unit detecting voltages of the secondary battery; a current detection unit detecting charge/discharge currents of the secondary battery; an internal resistance calculation unit calculating an internal resistance value of the secondary battery based on a voltage difference between the voltages detected by the voltage detection unit before and after the start of charging the secondary battery and a current difference between the charge/discharge currents detected by the current detection unit before and after the start of charging the secondary battery; a degradation determining unit determining whether the secondary battery is degraded by comparing the internal resistance value calculated by the internal resistance calculation unit with a degradation determining threshold of the secondary battery; and an output unit outputting a signal indicating the determination result of the degradation determining unit.

The internal resistance calculation unit is preferably configured to calculate the internal resistance value based on the voltage difference between a first voltage detected by the voltage detection unit before a charge current of the secondary battery greater than or equal to a predetermined value is detected and a second voltage detected by the voltage detection unit after the charge current greater than or equal to the predetermined value is detected, and the current difference between a first charge/discharge current detected by the current detection unit before the charge current greater than or equal to the predetermined value is detected and a second charge/discharge current detected by the current detection unit after the charge current greater than or equal to the predetermined value is detected.

Also, the internal resistance calculation unit is preferably configured to calculate the internal resistance value based on the voltage difference and the current difference obtained before the secondary battery starts to supply power to the electric load; and the degradation determining unit is preferably configured to determine whether the secondary battery is degraded using the internal resistance value calculated before the secondary battery starts to supply power to the electric load as the degradation determining threshold.

The degradation determining threshold is preferably stored in a rewritable memory.

The electric load may be an apparatus that performs a predetermined process based on the determination result of the degradation determining unit; and the output unit may be configured to output the signal indicating the determination result of the degradation determining unit to the apparatus.

The internal resistance calculation unit is preferably configured to correct the internal resistance value based on an ambient temperature around the secondary battery and/or a remaining charge level of the secondary battery.

In another aspect of this disclosure, there is provided a device detecting the status of a secondary battery supplying power to an electric load. The device includes a voltage detection unit detecting voltages of the secondary battery; a current detection unit detecting charge/discharge currents of the secondary battery; an internal resistance calculation unit calculating an internal resistance value of the secondary battery based on a voltage difference between the voltages detected by the voltage detection unit before and after the start of discharging of the secondary battery and a current difference between the charge/discharge currents detected by the current detection unit before and after the start of discharging of the secondary battery; a degradation determining unit determining whether the secondary battery is degraded by comparing the internal resistance value calculated by the internal resistance calculation unit with a degradation determining threshold of the secondary battery; and an output unit outputting a signal indicating the determination result of the degradation determining unit.

The internal resistance calculation unit is preferably configured to calculate the internal resistance value based on the voltage difference between a first voltage detected by the voltage detection unit before a discharge current of the secondary battery greater than or equal to a predetermined value is detected and a second voltage detected by the voltage detection unit after the discharge current greater than or equal to the predetermined value is detected, and the current difference between a first charge/discharge current detected by the current detection unit before the discharge current greater than or equal to the predetermined value is detected and a second charge/discharge current detected by the current detection unit after the discharge current greater than or equal to the predetermined value is detected.

### Advantageous Effect of the Invention

An aspect of the present invention makes it possible to determine whether a secondary battery is degraded even if the consumption current of an electric load receiving power from the secondary battery varies frequently.

### BRIEF DESCRIPTION OF THE DRAWINGS

FIG. 1 is a drawing illustrating a configuration of an intelligent battery pack 100A that is a first embodiment of a battery status detection device;

FIG. 2 is a flowchart showing a process performed by a management system of the battery pack 100A;

FIG. 3 is a graph showing temperature characteristics of resistance values Rc calculated at different numbers of charge-discharge cycles;

FIG. 4 is a graph showing temperature characteristics of resistance values Rcomp obtained by correcting the resistance values Rc based on detected temperatures;

FIG. 5 is a graph showing remaining-charge-level characteristics of resistance values Rcomp calculated at different numbers of charge-discharge cycles;

FIG. 6 is a graph showing remaining-charge-level characteristics of resistance values Rcomp2 obtained by correcting the resistance values Rcomp based on remaining charge levels;

FIG. 7 is a table showing changes in the voltage of an unused lithium-ion battery being charged with a pulse charge current of 0.5 C;

FIG. 8 is a graph showing changes in the voltage of an unused lithium-ion battery being charged with a pulse charge current of 0.5 C;

FIG. 9 is a table showing changes in the voltage of an unused lithium-ion battery being charged with a pulse charge current of 1.0 C;

FIG. 10 is a graph showing changes in the voltage of an unused lithium-ion battery being charged with a pulse charge current of 1.0 C;

FIG. 11 is a table showing changes in the voltage of a lithium-ion battery that has gone through 500 charge-discharge cycles and is being charged with a pulse charge current of 0.5 C;

FIG. 12 is a graph showing changes in the voltage of a lithium-ion battery that has gone through 500 charge-discharge cycles and is being charged with a pulse charge current of 0.5 C;

FIG. 13 is a table showing changes in the voltage of a lithium-ion battery that has gone through 500 charge-discharge cycles and is being charged with a pulse charge current of 1.0 C;

FIG. 14 is a graph showing changes in the voltage of a lithium-ion battery that has gone through 500 charge-discharge cycles and is being charged with a pulse charge current of 1.0 C;

FIG. 15 is a drawing showing a current detection process; and

FIG. 16 is a graph showing “open-circuit voltage−percentage of charge” characteristics at 25° C.

### BEST MODE FOR CARRYING OUT THE INVENTION

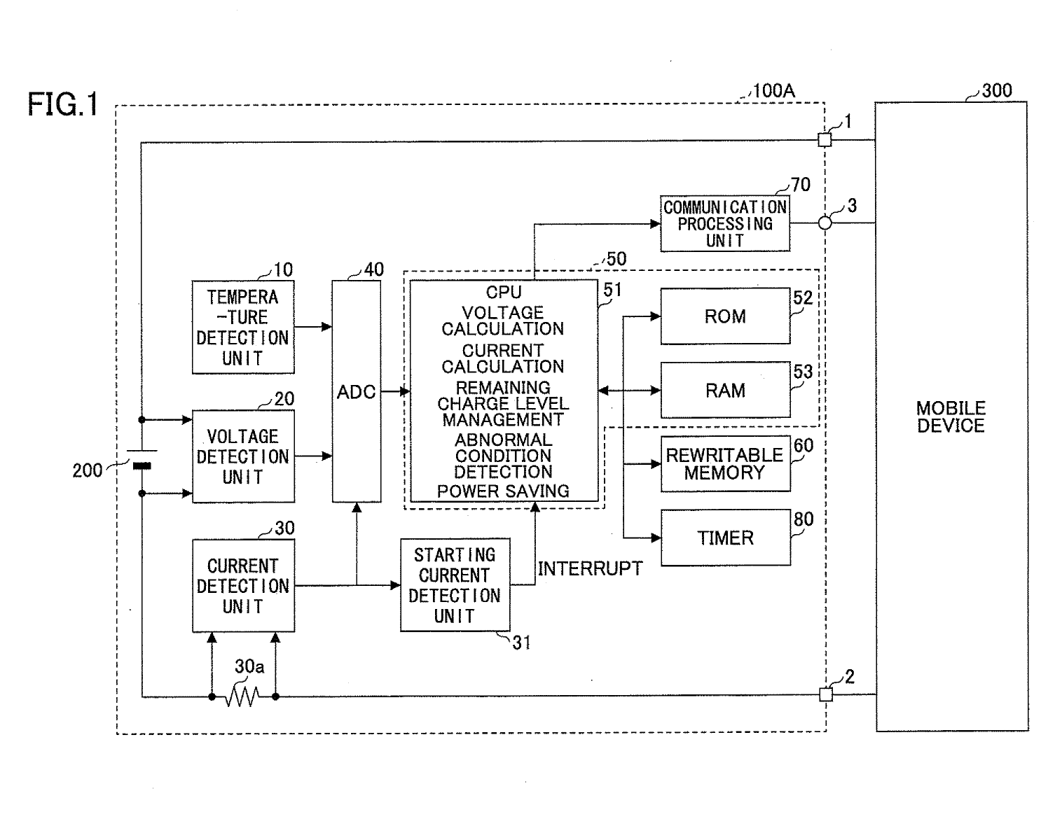

Preferred embodiments of the present invention are described below with reference to the accompanying drawings. FIG. 1 is a drawing illustrating a configuration of an intelligent battery pack 100A that is a first embodiment of a battery status detection device. The battery pack 100A includes a secondary battery 200 such as a lithium-ion battery, a nickel-hydrogen battery, or an electric double layer capacitor; a temperature detection unit 10 for detecting the ambient temperature around the secondary battery 200; a voltage detection unit 20 for detecting the voltage of the secondary battery 200; a current detection unit 30 for detecting the charge/discharge current of the secondary battery 200; an AD converter (ADC) 40 for converting analog voltage values indicating detection results of the detection units 10, 20, and 30 into digital values; an arithmetic processing unit 50 (e.g., a microcomputer including a CPU 51, a ROM 52, and a RAM 53) for calculating, for example, an integral (or sum) of current values, a corrected capacity, and a discharge capacity; a memory 60 (e.g., EEPROM or flash memory) for storing characteristics data used in calculations by the arithmetic processing unit 50 to identify characteristics of the secondary battery 200 and other components of the buttery pack 100A; a communication processing unit 70 (e.g., communication IC) for transmitting battery status information of the secondary battery 200 to a mobile device 300 receiving power from the secondary battery 200; a timer 80 for managing time; and a starting current detection unit 31 for detecting the starting current of the mobile device 300 based on a detection result of the current detection unit 30. Some or all of these components may be implemented as a packaged integrated circuit.

Thus, the battery pack 100A is a module including the secondary battery 200 and a management system for managing the status of the secondary battery 200. The battery pack 100A is connected via electrodes (a positive electrode 1 and a negative electrode 2) and a communication terminal 3 to the mobile device 300. The positive electrode 1 is electrically connected via an electric path to the positive terminal (cathode) of the secondary battery 200 and the negative electrode 2 is connected via an electric path to the negative terminal (anode) of the secondary battery 200. The communication terminal 3 is connected to the communication processing unit 70. The communication processing unit 70 reports information indicating processing results of the arithmetic processing unit 50 to the mobile device 300.

The mobile device 300 is a portable electronic device to be carried by a person. Examples of the mobile device 300 include a mobile phone, an information terminal such as a personal digital assistant (PDA) or a mobile PC, a camera, a game console, and a music or video player. The battery pack 100A may be embedded in the mobile device 300 or externally attached to the mobile device 300. The mobile device 300 receives battery status information from the communication processing unit 70 and performs a predetermined process according to the received battery status information. For example, the mobile device 300 displays the battery status information (e.g., information indicating the remaining charge level, the degradation, and/or the replacement time of the secondary battery 200) on a display unit or changes operational modes (e.g., from a normal power consumption mode to a low power consumption mode) based on the battery status information.

The secondary battery 200 supplies power to the mobile device 300 as well as to the ADC 40, the arithmetic processing unit 50, the communication processing unit 70, and the timer 80. The temperature detection unit 10, the voltage detection unit 20, the current detection unit 30, and the starting current detection unit 31 may also need power supply from the secondary battery 200 depending on their circuit configurations. The memory 60 can retain stored information even if power supply from the secondary battery 200 is stopped. The temperature detection unit 10, the voltage detection unit 20, the current detection unit 30, the ADC 40, and the arithmetic processing unit 50 collectively function as a status detection unit for detecting the status of the secondary battery 200.

The temperature detection unit 10 detects the ambient temperature around the secondary battery 200, converts the detected ambient temperature into a voltage that can be input to the ADC 40, and outputs the voltage to the ADC 40. The ADC 40 converts the voltage into a digital value indicating the ambient temperature around the secondary battery 200 and outputs the digital value to the arithmetic processing unit 50 that uses the digital value as a parameter for calculations. Also, the arithmetic processing unit 50 converts the digital value indicating the ambient temperature around the secondary battery 200 into a predetermined unit of measurement and outputs the converted digital value as battery status information of the secondary battery 200 via the communication processing unit 70 to the mobile device 300. When the secondary battery 200 and other components of the battery pack 100A are disposed close to each other, the temperature detection unit 10 may be configured to detect, in addition to the temperature of the secondary battery 200 and the ambient temperature around the secondary battery 200, the temperatures of other components of the battery pack 100A. Also, when the temperature detection unit 10, the voltage detection unit 20, the current detection unit 30, and the ADC 40 are combined as an integrated circuit, the temperature detection unit 10 may be configured to also detect the temperature of the integrated circuit and the ambient temperature around the integrated circuit.

The voltage detection unit 20 detects the voltage of the secondary battery 200, converts the detected voltage into a voltage that can be input to the ADC 40, and outputs the converted voltage to the ADC 40. The ADC 40 converts the voltage into a digital value indicating the voltage of the secondary battery 200 and outputs the digital value to the arithmetic processing unit 50 that uses the digital value as a parameter for calculations. Also, the arithmetic processing unit 50 converts the digital value indicating the voltage of the secondary battery 200 into a predetermined unit of measurement and outputs the converted digital value as battery status information of the secondary battery 200 via the communication processing unit 70 to the mobile device 300.

The current detection unit 30 detects the charge/discharge current of the secondary battery 200, converts the detected charge/discharge current into a voltage that can be input to the ADC 40, and outputs the voltage to the ADC 40. The current detection unit 30 includes a current detection resistor 30a connected in series with the secondary battery 200 and an operational amplifier for amplifying the voltage between the ends of the current detection resistor 30a. Thus, the current detection unit 30 converts the charge/discharge current into a voltage using the current detection resistor 30a and the operational amplifier. The operational amplifier may instead be included in the ADC 40. The ADC 40 converts the voltage into a digital value indicating the charge/discharge current of the secondary battery 200 and outputs the digital value to the arithmetic processing unit 50 that uses the digital value as a parameter for calculations. The arithmetic processing unit 50 also converts the digital value indicating the charge/discharge current of the secondary battery 200 into a predetermined unit of measurement and outputs the converted digital value as battery status information of the secondary battery 200 via the communication processing unit 70 to the mobile device 300.

The arithmetic processing unit 50 calculates the remaining charge level of the secondary battery 200. The remaining charge level may be calculated by any appropriate method. Exemplary methods of calculating the remaining charge level are described below.

The arithmetic processing unit 50 integrates (or adds up) current values detected by the current detection unit 30 while the secondary battery 200 is being charged or discharging (e.g., when a current greater than a predetermine value is being consumed by the mobile device 300) to calculate the amount of charged or discharged electricity of the secondary battery 200 and thereby to calculate the current amount of electricity (the remaining charge level) in the secondary battery 200. Here, Japanese Patent Application Publication No. 2004-226393 discloses a theory that even if conditions such as the temperature and the current change during a charging or discharging process, the charge/discharge efficiency does not change, but the amount of electricity that becomes temporarily not chargeable or dischargeable changes depending on the conditions. According to this theory, it is not necessary to correct the charge/discharge efficiency level based on the conditions.

However, if the battery pack 100A includes a component (hereafter called a temperature dependent circuit) that is affected by the temperature, the arithmetic processing unit 50 may be configured to detect the ambient temperature using the temperature detection unit 10 and to correct a charge/discharge current value of the secondary battery 200, which is converted by the ADC 40, based on “charge/discharge current−temperature” characteristics. The “charge/discharge current−temperature” characteristics are, for example, represented by a correction table or a correction function. In this case, data of the correction table or coefficients of the correction function are stored as characteristics data in the memory 60. The arithmetic processing unit 50 corrects the charge/discharge current value based on the temperature detected by the temperature detection unit 10 and the correction table or the correction function to which the characteristics data read from the memory 60 are applied.

When the mobile device 300 is in an inactive state (e.g., when the mobile device 300 is turned off or in a standby mode) and the secondary battery 200 is not being charged or discharging, the charge/discharge current value is smaller than that detected during a charging or discharging process. Therefore, while the mobile device 300 is in the inactive state, it is difficult to accurately detect the current value using the current detection unit 30 and the ADC 40 with limited resolutions. If the inactive state continues for a certain period of time, errors in detected current values (or in current integration) are accumulated and it becomes difficult to accurately calculate the remaining charge level of the secondary battery 200. To prevent this problem, the arithmetic processing unit 50 may be configured to stop integrating (or adding up) the current values or to integrate consumption current values of the mobile device 300 previously detected and stored in the memory 60.

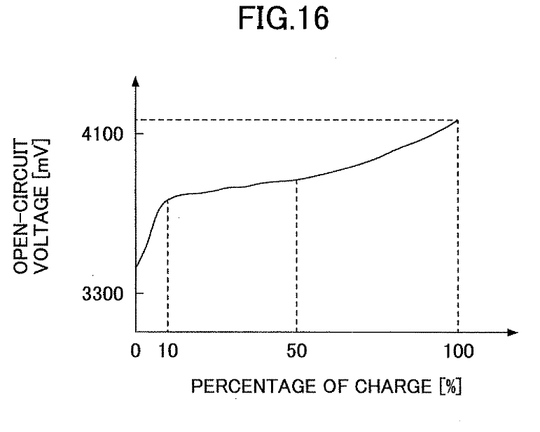

Also, to improve the accuracy of calculating the remaining charge level and the percentage of charge, if the inactive state of the mobile device 300 continues for a predetermined period of time, the arithmetic processing unit 50 periodically measures the voltage (the open-circuit voltage) of the secondary battery 200, and calculates and corrects the percentage of charge based on “open-circuit voltage−percentage of charge” characteristics (see FIG. 16). The open-circuit voltage is a voltage between the terminals of a stable secondary battery which is measured with the terminals open-circuited or with high impedance between the terminals. The percentage of charge indicates the percentage of the remaining charge level with respect to the full capacity (100) of the secondary battery. The “open-circuit voltage−percentage of charge” characteristics are, for example, represented by a correction table or a correction function. Data of the correction table or coefficients of the correction function are stored as characteristics data in the memory 60. The arithmetic processing unit 50 calculates and corrects the percentage of charge corresponding to the open-circuit voltage detected by the voltage detection unit 20 according to the correction table or the correction function to which the characteristics data read from the memory 60 are applied.

When the open-circuit voltage of the secondary battery 200 has a temperature characteristic, the arithmetic processing unit 50 may be configured to correct the open-circuit voltage based on a detected temperature. For example, the arithmetic processing unit 50 may be configured to detect the ambient temperature using the temperature detection unit 10 and to correct the open-circuit voltage of the secondary battery 200, which is converted by the ADC 40, based on “open-circuit voltage−temperature” characteristics. The “open-circuit voltage−temperature” characteristics are, for example, represented by a correction table or a correction function. Data of the correction table or coefficients of the correction function are stored as characteristics data in the memory 60. The arithmetic processing unit 50 corrects the open-circuit voltage based on the temperature detected by the temperature detection unit 10 and the correction table or the correction function to which the characteristics data read from the memory 60 are applied.

As described above, the arithmetic processing unit 50 calculates the percentage of charge of the secondary battery 200 with respect to the full capacity of the secondary battery 200. Therefore, it is necessary to measure or estimate the full capacity of the secondary battery 200 to calculate the percentage of charge of the secondary battery 200.

The full capacity of the secondary battery 200 may be calculated, for example, based on the amount of discharged electricity (first method) or the amount of charged electricity (second method). When the secondary battery 200 is charged with a constant voltage or a constant current instead of a pulse charge current, it is possible to more accurately measure the full capacity of the secondary battery 200 based on the amount of charged electricity instead of the amount of discharged electricity that is prone to be affected by the consumption current characteristics of the mobile device 300. One or both of the first and second methods may be selected taking into account the characteristics of the mobile device 300.

To accurately measure the full capacity of the secondary battery 200, it is necessary to integrate (or add up) current values detected while the secondary batter 200 is charged continuously from the zero charge level to the full charge level. However, it is rare to charge a battery from the zero charge level to the full charge level. Instead, a user would normally charge a battery while a certain amount of charge is left.

For this reason, the arithmetic processing unit 50 is configured to calculate the full capacity of the secondary battery 200 based on the battery voltage immediately before the start of charging and the battery voltage after a predetermined period of time from the end of charging. More specifically, the arithmetic processing unit 50 calculates the percentage of charge immediately before the start of charging based on the battery voltage immediately before the start of charging and the “open-circuit voltage−percentage of charge” characteristics (see FIG. 16); and also calculates the percentage of charge after a predetermined period of time from the end of charging based on the battery voltage after the predetermined period of time from the end of charging and the “open-circuit voltage−percentage of charge” characteristics (see FIG. 16). When the full capacity is FCC [mAh], the percentage of charge immediately before the start of charging is SOC1 [%], the percentage of charge after the predetermined period of time from the end of charging is SOC2 [%], and the amount of charged electricity during a charging period from the start of charging to the end of charging is Q [mAh], the arithmetic processing unit 50 calculates the full capacity FCC of the secondary battery 200 using a formula (1) below.

FCC=Q/{(SOC2−SOC1)/100} (1)

The values of SOC1 and SOC2 may be corrected according to a detected temperature to more accurately calculate FCC. Using the battery voltage after the predetermined period of time from the end of charging, which is more stable than the battery voltage at the end of charging, makes it possible to improve the accuracy of calculations.

With the percentage of charge and the full capacity calculated as described above, it is possible to calculate the remaining charge level of the secondary battery 200 (remaining charge level=full capacity X percentage of charge).

Meanwhile, the consumption current of a recent electric device such as a mobile phone changes frequently, for example, to increase the battery operating time. Therefore, it is difficult to accurately and stably detect the charge/discharge current and the voltage of a secondary battery by simply performing a detection process periodically. For this reason, in this embodiment, the internal resistance value of the secondary battery 200 is calculated based on a difference between the charge/discharge current value immediately before the start of charging and the charge/discharge current value after a predetermined period of time from the start of charging and a difference between the battery voltage immediately before the start of charging and the battery voltage after the predetermined period of time from the start of charging. The calculated internal resistance value is used to determine whether the secondary battery 200 is degraded.

When the battery voltage immediately before the start of charging is V0, the charge current immediately before the start of charging is I0, the battery voltage immediately before the start of charging is V1, and the charge current after the predetermined period of time from the start of charging is I1, an internal resistance value Rc of the secondary battery 200 is obtained by a formula (2) below. Here, it is assumed that the internal resistance value immediately before the start of charging and the internal resistance value after the predetermined period of time from the start of charging are substantially the same.

Rc=(V1−V0)/(I1−I0) (2)

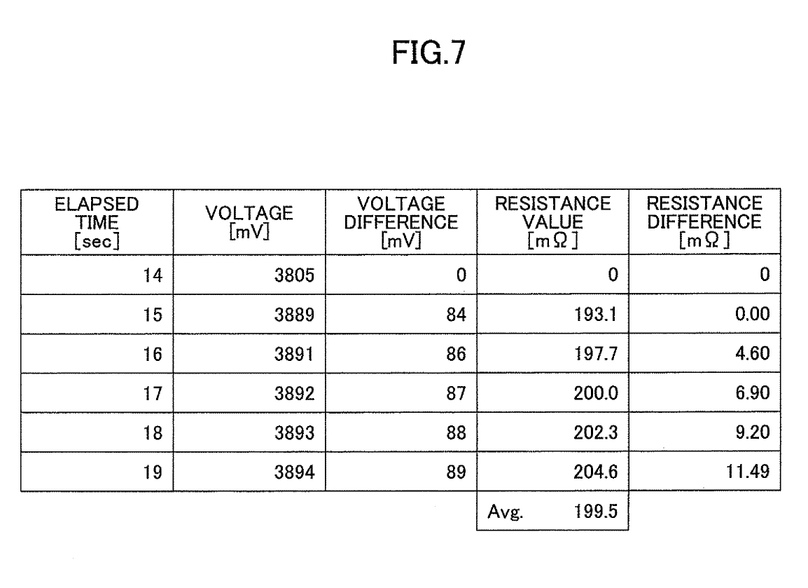

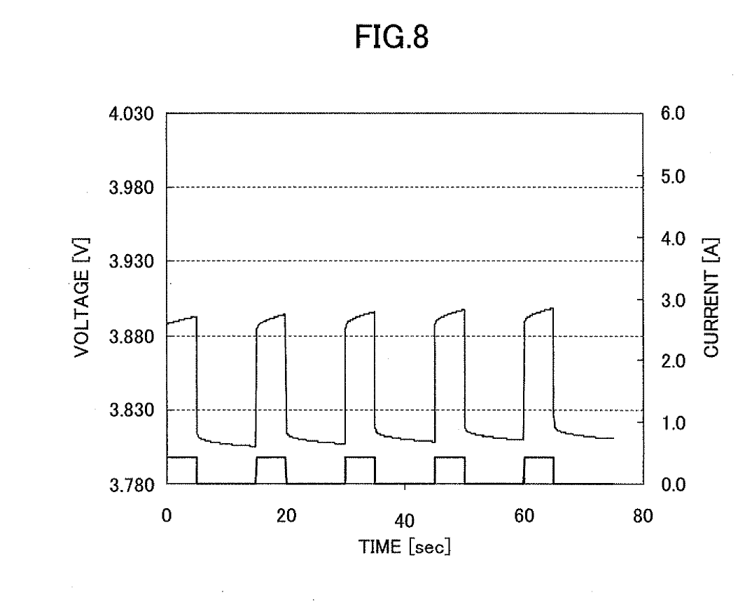

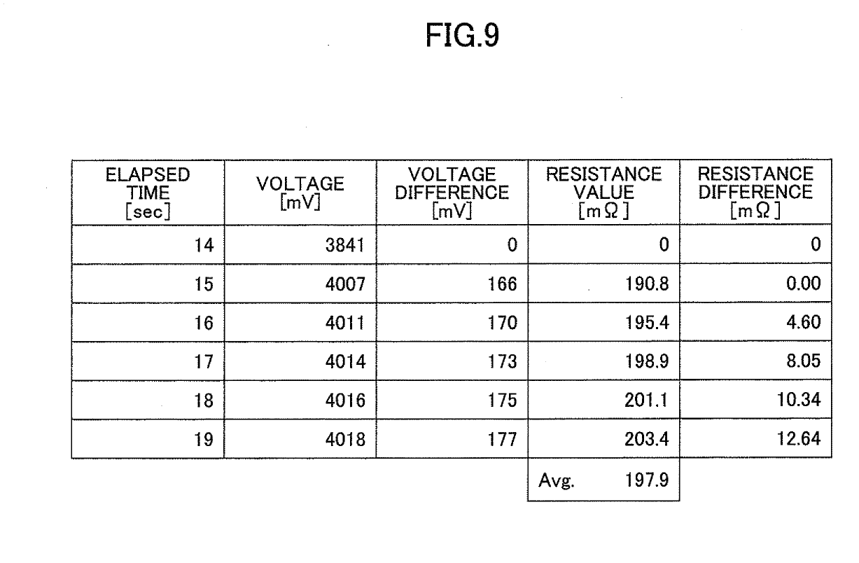

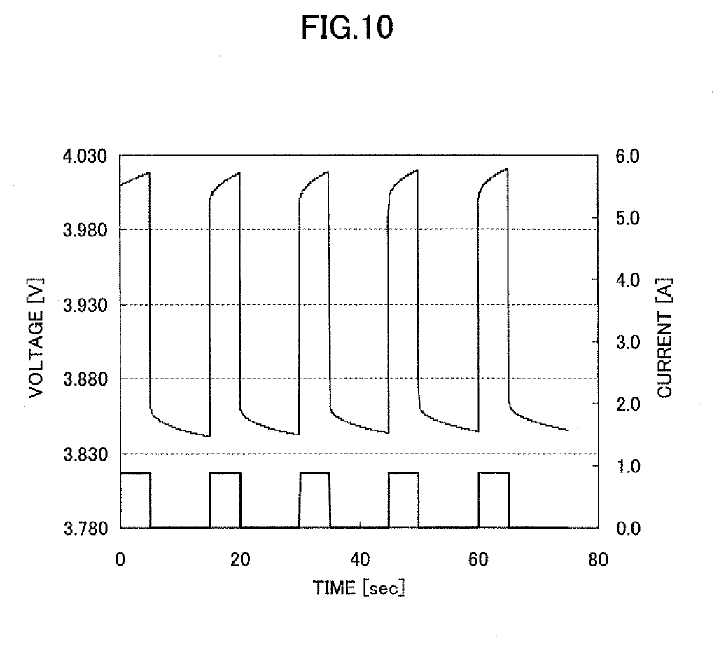

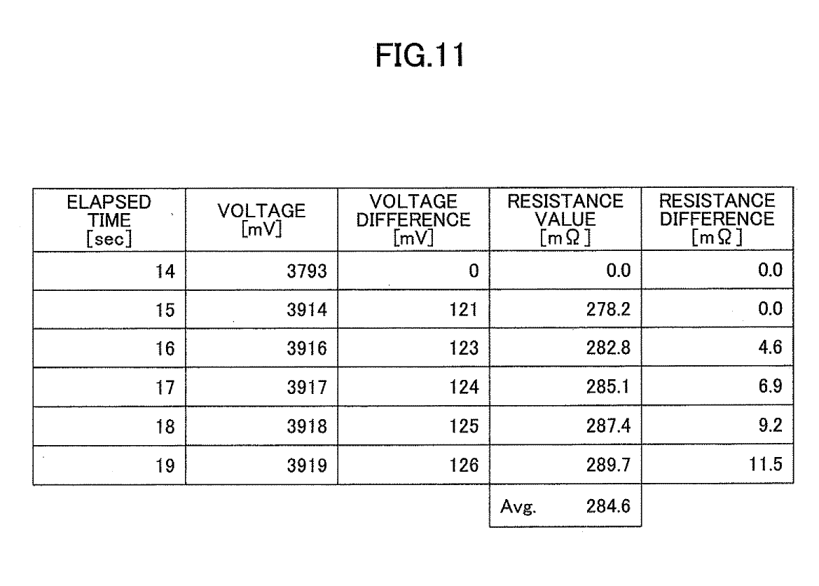

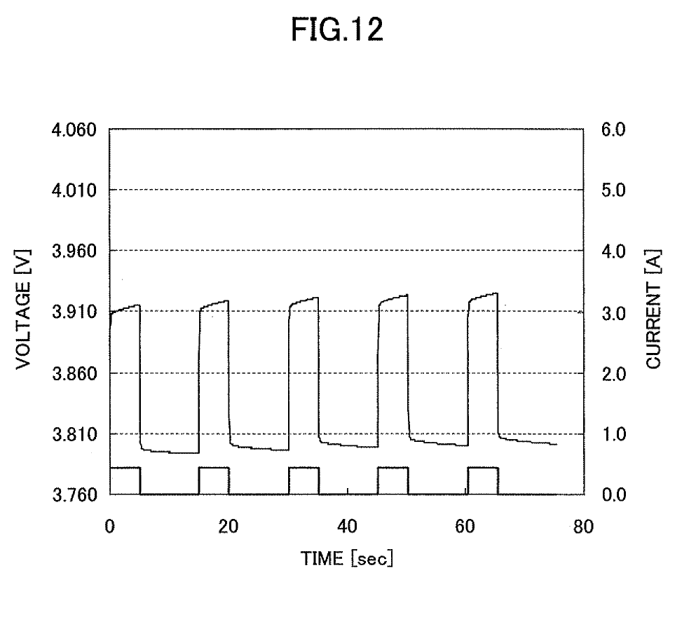

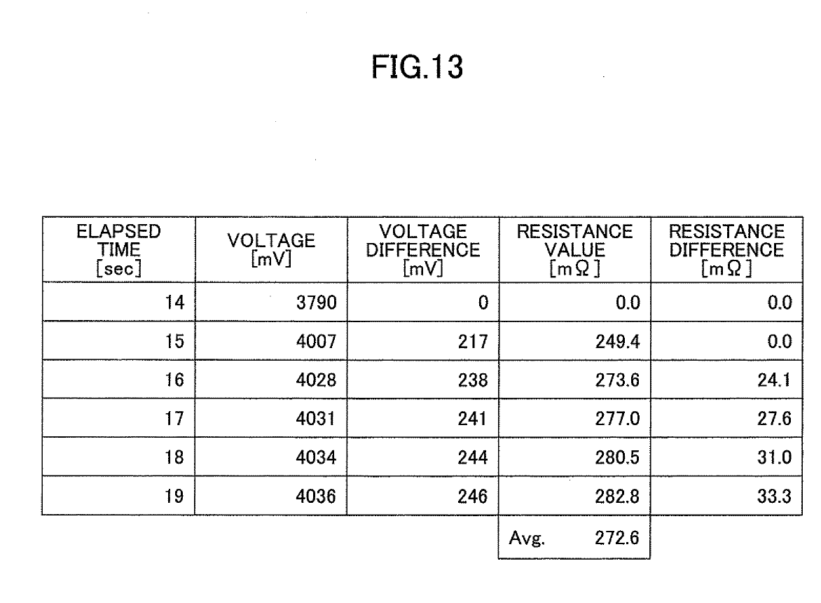

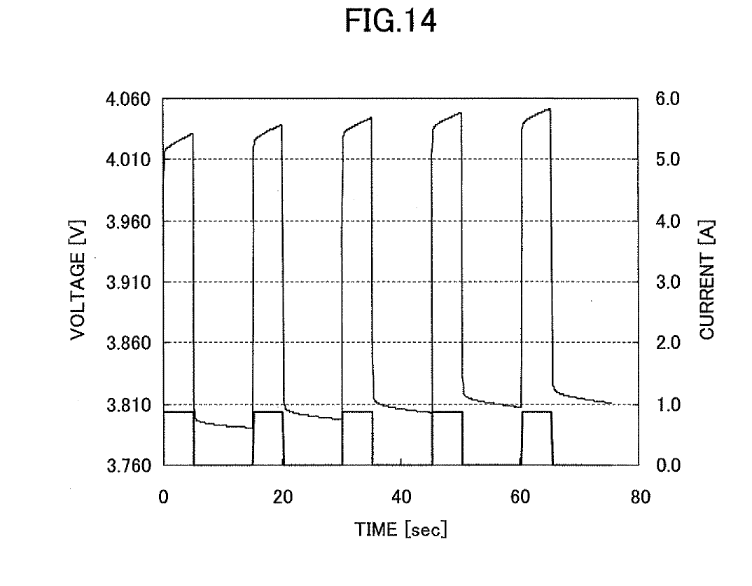

A test was conducted to confirm whether the internal resistance value could be stably obtained by specifying currents and voltages detected before and after the start of charging in the formula (2) above. In the test, a charging pulse for a secondary battery was generated five times and the voltage of the secondary battery during charging was detected at the corresponding timing. FIGS. 7 through 14 show the results of the test. FIGS. 7 and 8 show changes in the voltage of an unused lithium-ion battery being charged with a pulse charge current of 0.5 C. FIGS. 9 and 10 show changes in the voltage of an unused lithium-ion battery being charged with a pulse charge current of 1.0 C. FIGS. 11 and 12 show changes in the voltage of a lithium-ion battery that has gone through 500 charge-discharge cycles and is being charged with a pulse charge current of 0.5 C. FIGS. 13 and 14 show changes in the voltage of a lithium-ion battery that has gone through 500 charge-discharge cycles and is being charged with a pulse charge current of 1.0 C.

In the graphs of FIGS. 7, 9, 11, and 13, the elapsed time of 14 seconds corresponds to a trough of a voltage fluctuation waveform where the pulse charge current is not being supplied; and the elapsed times of 15 through 19 seconds correspond to peaks of the voltage fluctuation waveform where the pulse charge current is being supplied.

An average internal resistance value was calculated based on differences between the voltage at the trough and the voltages at the peaks of the voltage fluctuation waveform for each of the cases of FIGS. 7 and 8 and FIGS. 9 and 10. The average internal resistance value in the case of FIGS. 7 and 8 was 199.5 mΩ and the average internal resistance value in the case of FIGS. 9 and 10 was 197.9 mΩ. Thus, the average internal resistance values in the two cases were substantially the same. This result shows that it is possible to stably calculate the internal resistance value based on voltages detected before and after the start of charging regardless of the charge current level.

Similarly, an average internal resistance value was calculated based on differences between the voltage at the trough and the voltages at the peaks of the voltage fluctuation waveform for each of the cases of FIGS. 11 and 12 and FIGS. 13 and 14. The average internal resistance value in the case of FIGS. 11 and 12 was 284.6 mΩ and the average internal resistance value in the case of FIGS. 13 and 14 was 272.6 mΩ. Thus, the average internal resistance values in the two cases were substantially the same. This result shows that it is even possible to stably calculate the internal resistance value of a battery that is degraded after use based on voltages detected before and after the start of charging regardless of the charge current level.

If an inactive state where the charge/discharge current of the secondary battery 200 is zero or very small is detected for a predetermined period of time and then a charging state where the charge current of the secondary battery 200 is greater than or equal to a predetermined value, which is greater than the charge/discharge current in the inactive state, is detected, the arithmetic processing unit 50 calculates the internal resistance value of the secondary battery 200 using the formula (2) above based on the voltage and the current of the secondary battery 200 detected in the charging state, i.e., after a predetermined period of time from when the charge current greater than or equal to the predetermined value is detected and the voltage and the current of the secondary battery 200 detected in the inactive state, i.e., before the charge current greater than or equal to the predetermined value is detected. The arithmetic processing unit 50 compares the calculated internal resistance value with a predetermined resistance value (stored, for example, in the memory 60) at which the secondary battery 200 is assumed to be degraded and determines that the secondary battery 200 is degraded if the calculated internal resistance value is greater than the predetermined resistance value. The determination result is sent via the communication processing unit 70 to the mobile device 300.

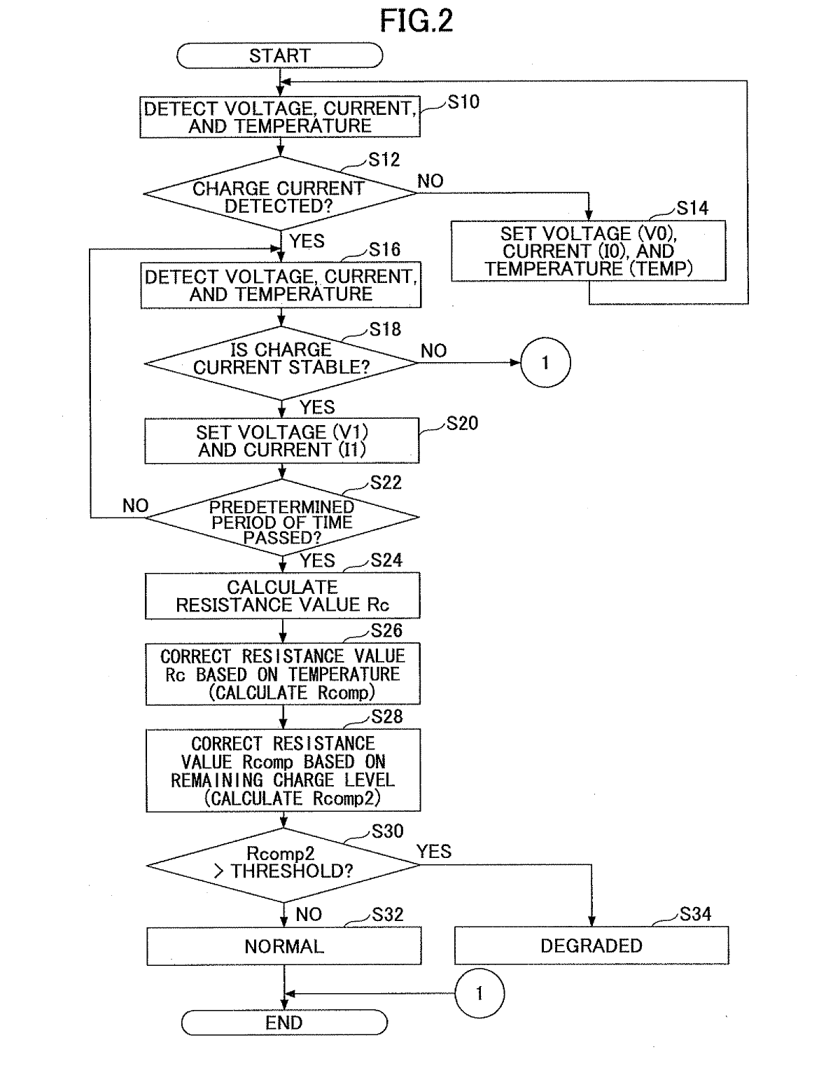

FIG. 2 is a flowchart showing a process performed by the management system of the battery pack 100A. In the management system, the arithmetic processing unit 50 mainly controls the process. After initializing the management system, the arithmetic processing unit 50 detects the temperature, the voltage, and the current of the secondary battery 200 using the temperature detection unit 10, the voltage detection unit 20, and the current detection unit 30 (step 10). In other words, the arithmetic processing unit 50 detects the temperature, the voltage, and the current measured by the detection units 10, 20, and 30 at a predetermined detection interval and stores a set of values detected at the same timing in a memory such as the RAM 53. The detection interval is determined, for example, by taking into account the rise characteristics of the voltage of the secondary battery 200 during a charging process so that the voltage difference between voltages and the current difference between currents detected before and after the rise of the voltage of the secondary battery 200 during a charging process can be accurately detected.

After an inactive state where the charge/discharge current of the secondary battery 200 is zero or very small is detected by the current detection unit 30 for a predetermined period of time, the arithmetic processing unit 50 determines whether the current detected by the current detection unit 30 is greater than or equal to a first current threshold for determining the start of charging the secondary battery 200 (step 12). If the current detected by the current detection unit 30 in step 10 is less than the first current threshold, the arithmetic processing unit 50 sets V0, I0, and Temp at the detected voltage, current, and temperature (step 14). V0, I0), and Temp indicate values detected immediately before the start of charging.

After step 14, the process returns to step 10. The values of V0, I0, and Temp are repeatedly updated until the current detected by the current detection unit 30 becomes greater than or equal to the first current threshold in step 12.

If the current detected by the current detection unit 30 in step 10 is less than the first current threshold (absolute value) and is a discharge current that is zero or greater than or equal to a predetermined value (absolute value) that is greater than zero, the detected current may be regarded as not suitable for calculating the internal resistance value and not used for this purpose.

Meanwhile, if it is determined, in step 12, that the current detected by the current detection unit 30 in step 10 is greater than or equal to the first current threshold, the arithmetic processing unit 50 determines that the charging of the secondary battery 200 has been started, and detects the temperature, the voltage, and the current of the secondary battery 200 again using the temperature detection unit 10, the voltage detection unit 20, and the current detection unit 30 (step 16). Next, the arithmetic processing unit 50 determines whether the current detected by the current detection unit 30 in step 16 is greater than or equal to a second current threshold that is greater than the first current threshold (step 18). The second current threshold is used to determine whether the charge current for the secondary battery 200 has risen and the charging process is in a stable charging state (where the fluctuation of the charge current is smaller than that before the charge current rises).

If the current detected by the current detection unit 30 in step 16 is less than the second current threshold, the arithmetic processing unit 50 determines that the charge current has not become stable after the start of charging and is not suitable for calculating the internal resistance value, and terminates the process. Meanwhile, if the current detected by the current detection unit 30 in step 16 is greater than or equal to the second current threshold, the arithmetic processing unit 50 determines that the charge current is stable and sets V1 and I1 at the detected voltage and current (step 20). V1 and I1 indicate values detected after a predetermined period of time from the start of charging. In step 22, if a predetermined period of time has not passed after the current greater than or equal to the first current threshold is detected, the arithmetic processing unit 50 determines that the charge current is still rising and returns to step 16. Meanwhile, if the predetermined period of time has passed after the current greater than or equal to the first current threshold is detected, the arithmetic processing unit 50 proceeds to step 24. In step 24, the arithmetic processing unit 50 calculates the internal resistance value Rc of the secondary battery 200 using the formula (2) above.

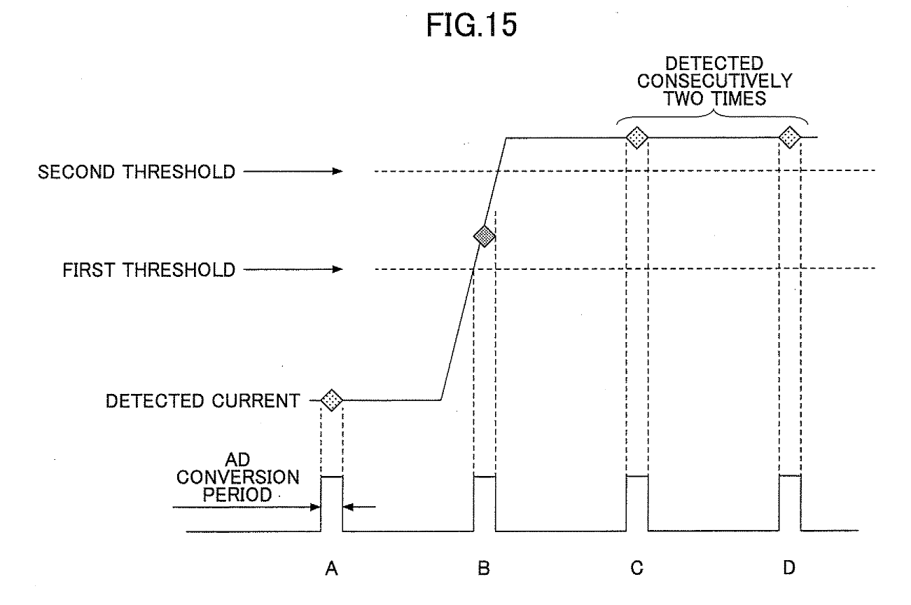

Thus, in this embodiment, the internal resistance value Rc is calculated each time when the secondary battery 200 is charged. Also in this embodiment, the first current threshold for determining the start of charging and the second current threshold greater than the first current threshold are used as shown in FIG. 15. This configuration makes it possible to correctly determine the timing when charging the secondary battery 200 is started and thereby to use values detected in a stable charging state to calculate the internal resistance value.

If the mobile device 300 intermittently consumes current (e.g., when a normal power consumption mode and a low power consumption mode are switched intermittently or when the consumption current periodically increases from a normal value of 1 mA to 100 mA) and the detection timing of the current I0 before the start of charging or the current I1 after the start of charging coincides with the rise timing of the charge current, the accuracy of the calculated internal resistance value is reduced. In this embodiment, however, the internal resistance value is calculated using two current thresholds as described above to take into account the operational state of the mobile device 300. This configuration makes it possible to reduce the error in the calculated internal resistance value. Also, to further reduce the error in the calculated internal resistance value by taking into account the operational state of the mobile device 300, an average of multiple detection values, an average of most-frequent detection values, or a detection value detected consecutively n-times may be used as a parameter of the formula (2).

If the secondary battery 200 and other components of the battery pack 100A have temperature characteristics, the internal resistance value Rc naturally has a temperature characteristic. For example, the open-circuit voltage of the secondary battery 200 tends to decrease as the ambient temperature increases. Also, the temperature detection unit 10, the voltage detection unit 20, the current detection unit 30, and the ADC 40 include analog devices such as a resistor, a transistor, and an amplifier and are therefore likely to be temperature dependent. Basically, an integrated circuit is designed taking into account the temperature dependency of devices on the wafer. However, due to manufacturing variations and characteristic variations of the wafer surface, a manufactured integrated circuit normally has small temperature dependency.

To obtain a stable result regardless of the temperature, the calculated internal resistance value may be corrected based on temperature information obtained during the calculation process. The arithmetic processing unit 50 corrects the internal resistance value Rc calculated in step 24 based on the ambient temperature to obtain a first corrected resistance value Rcomp (step 26).

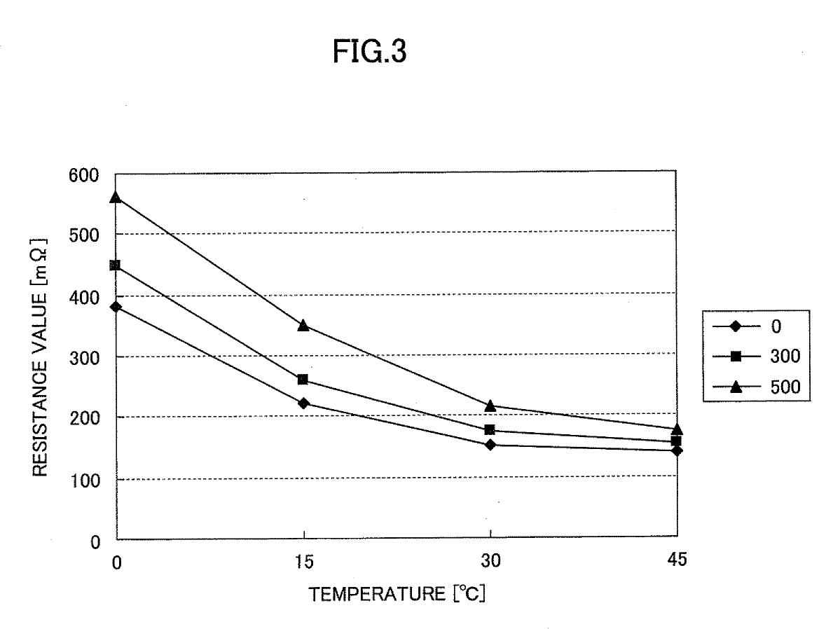

FIG. 3 is a graph showing temperature characteristics of resistance values Rc of the secondary battery 200 with a remaining charge level of 340 mAh which are calculated at different numbers of charge-discharge cycles. Although the resistance value Rc has to be constant regardless of the temperature, as shown in FIG. 3, the resistance value Rc decreases as the temperature increases due to the temperature characteristic of, for example, the ADC 40. Although details are omitted here, a first correction formula (3) that takes the ambient temperature Temp and the internal resistance value Rc as parameters is obtained by performing a curve fitting process on the temperature characteristics shown in FIG. 3. With the formula (3), it is possible to obtain a substantially constant internal resistance value regardless of the ambient temperature.

Rcomp=(0.0016×Temp²−0.006×Temp+0.7246)×Rc+(−0.3172×Temp²+8.6019×Temp−59.861) (3)

To calculate coefficients in the formula (3) by a curve fitting process, numerical analysis software such as MATLAB or LabVIEW may be used. The calculated coefficients are stored, for example, in the memory 60. The arithmetic processing unit 50 calculates the first corrected resistance value Rcomp by specifying the coefficients read from the memory 60, the temperature detected by the temperature detection unit 10, and the internal resistance value Rc in the formula (3).

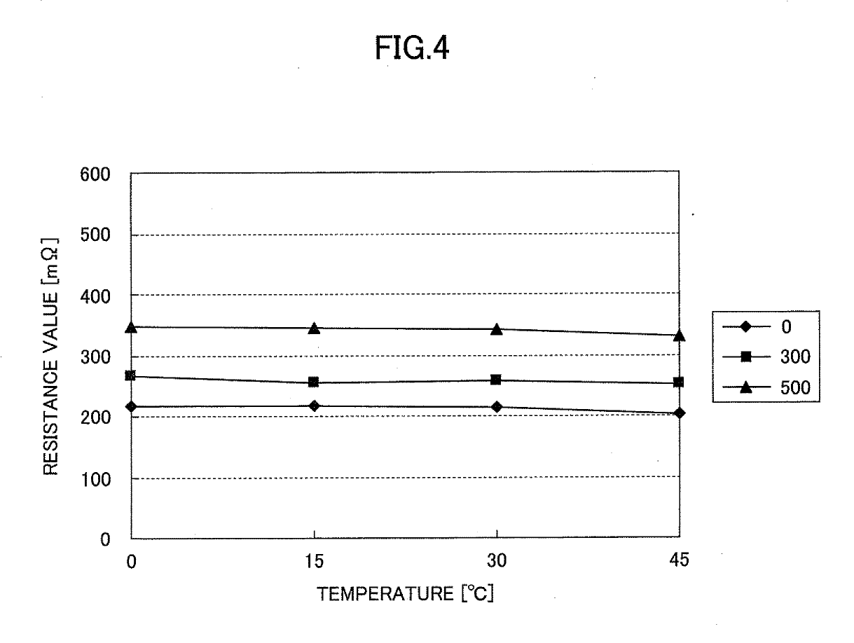

FIG. 4 is a graph showing temperature characteristics of the resistance values Rcomp obtained by correcting the resistance values Rc based on the temperatures. Using the correction formula (3) makes it possible to obtain a substantially constant internal resistance value as shown in FIG. 4 regardless of the ambient temperature around the secondary battery 200.

The calculated internal resistance value may also vary depending on the remaining charge level of the secondary battery 200. Therefore, the internal resistance value may also be corrected based on the remaining charge level detected during the calculation process. The arithmetic processing unit 50 corrects the resistance value Rcomp calculated in step 26 based on the remaining charge level to obtain a second corrected resistance value Rcomp2 (step 28).

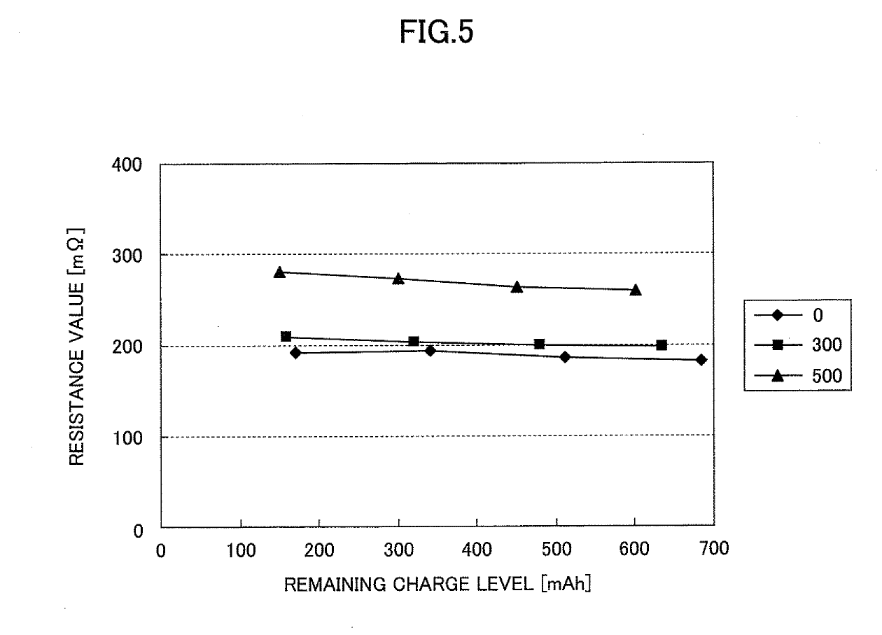

FIG. 5 is a graph showing remaining-charge-level characteristics of resistance values Rcomp calculated at different numbers of charge-discharge cycles when the ambient temperature is 20° C. Although the resistance value Rcomp has to be constant regardless of the remaining charge level, as shown in FIG. 5, the resistance value Rcomp decreases as the remaining charge level increases. Although details are omitted here, a second correction formula (5) that takes a remaining charge level Q0 immediately before the start of charging and the first corrected resistance value Rcomp as parameters is obtained by performing a curve fitting process on the remaining-charge-level characteristics shown in FIG. 5. With the formula (4), it is possible to obtain a substantially constant internal resistance value regardless of the remaining charge level.

Rcomp2=(0.0004×Q0+0.8543)×Rcomp+(−0.0504×Q0+19.804) (4)

The remaining charge level Q0 immediately before the start of charging is calculated by the arithmetic processing unit 50. To calculate coefficients in the formula (4) by a curve fitting process, numerical analysis software such as MATLAB or LabVIEW may be used. The calculated coefficients are stored, for example, in the memory 60. The arithmetic processing unit 50 calculates the second corrected resistance value Rcomp2 by specifying the coefficients read from the memory 60, the remaining charge level Q0, and the first corrected resistance value Rcomp in the formula (4).

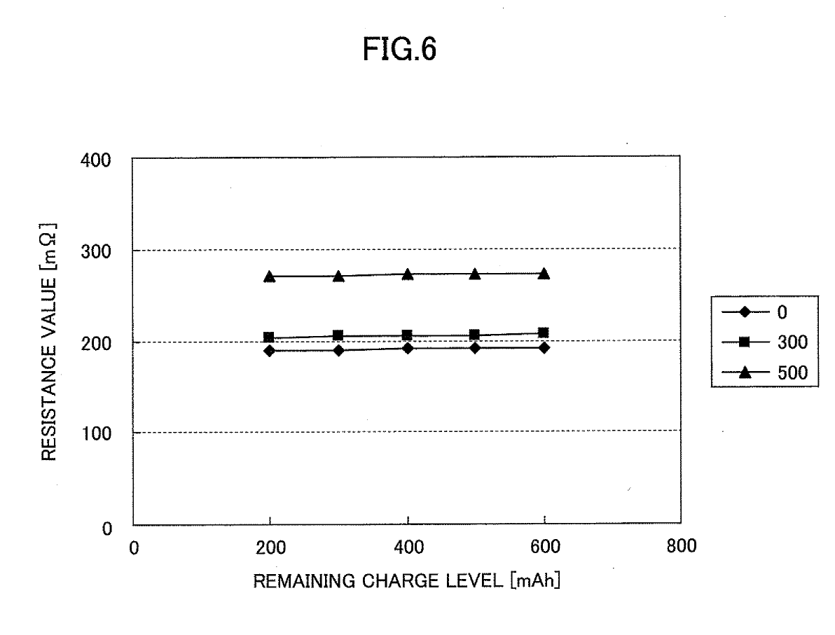

FIG. 6 is a graph showing remaining-charge-level characteristics of resistance values Rcomp2 obtained by correcting the resistance values Rcomp based on remaining charge levels. Using the correction formula (4) makes it possible to obtain a substantially constant internal resistance value as shown in FIG. 6 regardless of the remaining charge level of the secondary battery 200.

Referring back to FIG. 2, the arithmetic processing unit 50 determines whether the resistance value Rcomp2 is greater than a degradation determining threshold (step 30). If the resistance value Rcomp2 is greater than the degradation determining threshold, the arithmetic processing unit 50 determines that the secondary battery 200 is degraded (step 34). Meanwhile, if the resistance value Rcomp2 is less than or equal to the degradation determining threshold, the arithmetic processing unit 50 determines that the secondary battery 200 is not degraded, i.e., normal (step 32). The arithmetic processing unit 50 may be configured to determine the degree of degradation of the secondary battery 200 by comparing the resistance value Rcomp2 with multiple (different) degradation determining thresholds. This configuration makes it possible to more precisely determine the degradation of the secondary battery 200.

The degradation determining threshold(s) may be stored in the memory 60. The degradation determining threshold stored in the memory 60 may be changed depending on the specifications of the mobile device 300. This makes it possible to properly determine whether the secondary battery 200 is degraded even when the specifications of the mobile device 300 to which the battery pack 100A is attached are changed.

Also, the arithmetic processing unit 50 may be configured to calculate an initial internal resistance value based on values detected before the secondary battery 200 starts supplying power to the mobile device 300 and to determine whether the secondary battery 200 is degraded using the initial internal resistance value as the degradation determining threshold. In this case, the arithmetic processing unit 50 compares a current internal resistance value calculated based on values detected after the secondary battery 200 starts supplying power to the mobile device 300 with the initial internal resistance value to determine whether the secondary battery 200 is degraded (or the degree of degradation). For example, the arithmetic processing unit 50 may calculate the difference between the initial internal resistance value and the current internal resistance value and determine the degree of degradation of the secondary battery 200 based on the difference (e.g., the greater the difference is, the higher the degree of degradation is).

The initial internal resistance value may be calculated before the battery pack 100A is attached to the mobile device 300 (e.g., before the battery pack 100A is shipped) based on voltages and currents detected before and after starting to charge the secondary battery 200 for the first time. When an initial charging process of the secondary battery 200 is detected by, for example, the current detection unit 30, the arithmetic processing unit 50 calculates the initial internal resistance value based on values detected before and after the start of the initial charging process and stores the initial internal resistance value in the memory 60 as the degradation determining threshold. The initial charging process may be performed by supplying a pulse charge current from an external power supply via the electrodes 1 and 2 of the battery pack 100A.

In the above embodiment, whether the secondary battery 200 is degraded (and/or the degree of degradation of the secondary battery 200) is determined based on the difference between voltages and the difference between currents detected before and after the start of charging. This configuration makes it possible to properly determine the degradation of the secondary battery 200 even if the consumption current of the mobile device 300 varies frequently.

Also in the above embodiment, characteristics data (e.g., coefficients of the correction formulas (3) and (4) and the degradation determining threshold) used to calculate the internal resistance value and to determine the degradation of the secondary battery 200 are stored in the memory 60. Compared with a case where the internal resistance value is calculated based on a look-up table storing a large amount of characteristics data indicating, for example, “internal resistance value−temperature” characteristics and “internal resistance value−remaining charge level” characteristics, the above embodiment makes it possible to accurately calculate the internal resistance value and determine the degradation of the secondary battery 200 using a small memory area. Reducing the size of the memory area in turn makes it possible to reduce the costs of an integrated circuit. Also, the characteristics data stored in the memory 60 may be changed depending on the characteristics of the secondary battery. This makes it possible to calculate internal resistance values and to determine the degradation of secondary batteries with different characteristics.

Compared with the impedance that is measured based on an alternating current, the internal resistance value, which is calculated based on values detected before and after the start of charging, varies greatly depending on the degree of degradation. Therefore, it is possible to fairly accurately determine the degradation of a secondary battery by comparing a calculated internal resistance value with a threshold even if the calculated internal resistance value has a small error.

Also with the above embodiment, the internal resistance value is calculated within the battery pack 100A and therefore it is not necessary to provide a dedicated device and/or measuring circuit in the mobile device 300 to calculate the internal resistance value. Further in the above embodiment, the status of the secondary battery 200 is monitored from the beginning. For example, this makes it possible to detect an event where the internal resistance value that has been increasing begins to decrease, thereby to detect an abnormality such as a small-scale short circuit in the secondary battery 200, and to report the abnormality to the mobile device 300.

Preferred embodiments of the present invention are described above. However, the present invention is not limited to the specifically disclosed embodiments, and variations and modifications may be made without departing from the scope of the present invention.

For example, when a secondary battery is used for a mobile device in which the starting current and/or the discharge current is substantially constant at least for a short period of time, the internal resistance value may be calculated based on values detected before and after the start of discharging instead of values detected before and after the start of charging. Also, when a secondary battery is charged with a constant current, it is possible to cause a voltage drop by stopping the charging process for a certain period of time and to use the voltage drop as the start of discharging. This approach also makes it possible to accurately calculate the internal resistance value. It is also possible to cause a voltage rise by stopping a charging process and resuming the charging process after a certain period of time and to use the voltage rise as the start of charging. This approach also makes it possible to accurately calculate the internal resistance value.

In the above embodiment, the calculated internal resistance value is corrected based on the remaining charge level of the secondary battery to reduce the variation depending on the remaining charge level. However, as is apparent from the remaining-charge-level characteristics of internal resistance values shown in FIG. 5, the difference between an internal resistance value calculated when the remaining charge level is low and an internal resistance value calculated when the remaining charge level is high increases as the degradation of the secondary battery proceeds. Therefore, the amount of change in the internal resistance value per unit amount of change in the remaining charge level may be calculated and the degree of degradation of a battery may be determined based on the amount of change in the internal resistance value. That is, it can be assumed that the degree of degradation becomes greater as the amount of change in the internal resistance value per unit amount of change in the remaining charge level increases.

In the above embodiment, whether the secondary battery 200 is degraded is determined by comparing a corrected internal resistance value (Rcomp or Rcomp2) calculated using the correction formulas with the degradation determining threshold. Alternatively, whether the secondary battery 200 is degraded may be determined by comparing the internal resistance value Rc, which is not corrected, with multiple degradation determining thresholds provided for respective temperature ranges. Similarly, whether the secondary battery 200 is degraded may be determined by comparing the internal resistance value Rc with multiple degradation determining thresholds provided for respective ranges of the remaining charge level.

Also, the timing of detecting the voltage and the current after the start of charging for calculation of the internal resistance value may be changed based on values stored in the memory 60 for different types of secondary batteries. This configuration makes it possible to detect the voltage and the current after the start of charging at an optimum timing according to the type of secondary battery.

The present international application claims priority from Japanese Patent Application No. 2008-181924 filed on Jul. 11, 2008, the entire contents of which are hereby incorporated herein by reference.

### EXPLANATION OF REFERENCES

10 Temperature detection unit
20 Voltage detection unit
21 Starting voltage detection unit
30 Current detection unit
31 Starting current detection unit
40 ADC
50 Arithmetic processing unit
60 Memory
70 Communication processing unit
80 Timer
100A Battery pack
200 Secondary battery
300 Mobile device

1. A device detecting a status of a secondary battery supplying power to an electric load, the device comprising:
a voltage detection unit detecting voltages of the secondary battery;
a current detection unit detecting charge/discharge currents of the secondary battery;
an internal resistance calculation unit calculating an internal resistance value of the secondary battery based on a voltage difference between the voltages detected by the voltage detection unit before and after a start of charging the secondary battery and a current difference between the charge/discharge currents detected by the current detection unit before and after the start of charging the secondary battery;
a degradation determining unit determining whether the secondary battery is degraded by comparing the internal resistance value calculated by the internal resistance calculation unit with a degradation determining threshold of the secondary battery; and
an output unit outputting a signal indicating the determination result of the degradation determining unit.

2. The device as claimed in claim 1, wherein
the internal resistance calculation unit calculates the internal resistance value based on
the voltage difference between a first voltage detected by the voltage detection unit before a charge current of the secondary battery greater than or equal to a predetermined value is detected and a second voltage detected by the voltage detection unit after the charge current greater than or equal to the predetermined value is detected; and
the current difference between a first charge/discharge current detected by the current detection unit before the charge current greater than or equal to the predetermined value is detected and a second charge/discharge current detected by the current detection unit after the charge current greater than or equal to the predetermined value is detected.

3. The device as claimed in claim 1, wherein
the internal resistance calculation unit calculates the internal resistance value based on the voltage difference and the current difference obtained before the secondary battery starts to supply power to the electric load; and
the degradation determining unit determines whether the secondary battery is degraded using the internal resistance value calculated before the secondary battery starts to supply power to the electric load as the degradation determining threshold.

4. The device as claimed in claim 1, wherein the degradation determining threshold is stored in a rewritable memory.

5. The device as claimed in claim 1, wherein
the electric load is an apparatus that performs a predetermined process based on the determination result of the degradation determining unit; and
the output unit outputs the signal indicating the determination result of the degradation determining unit to the apparatus.

6. The device as claimed in claim 1, wherein the internal resistance calculation unit corrects the internal resistance value based on an ambient temperature around the secondary battery.

7. The device as claimed in claim 1, wherein the internal resistance calculation unit corrects the internal resistance value based on a remaining charge level of the secondary battery.

8. A device detecting a status of a secondary battery supplying power to an electric load, the device comprising:
a voltage detection unit detecting voltages of the secondary battery;
a current detection unit detecting charge/discharge currents of the secondary battery;
an internal resistance calculation unit calculating an internal resistance value of the secondary battery based on a voltage difference between the voltages detected by the voltage detection unit before and after a start of discharging of the secondary battery and a current difference between the charge/discharge currents detected by the current detection unit before and after the start of discharging of the secondary battery;
a degradation determining unit determining whether the secondary battery is degraded by comparing the internal resistance value calculated by the internal resistance calculation unit with a degradation determining threshold of the secondary battery; and
an output unit outputting a signal indicating the determination result of the degradation determining unit.

9. The device as claimed in claim 8, wherein
the internal resistance calculation unit calculates the internal resistance value based on
the voltage difference between a first voltage detected by the voltage detection unit before a discharge current of the secondary battery greater than or equal to a predetermined value is detected and a second voltage detected by the voltage detection unit after the discharge current greater than or equal to the predetermined value is detected, and
the current difference between a first charge/discharge current detected by the current detection unit before the discharge current greater than or equal to the predetermined value is detected and a second charge/discharge current detected by the current detection unit after the discharge current greater than or equal to the predetermined value is detected.
